(19) United States
(12) Patent Application Publication
(10) Pub. No.: US 2026/0324027 A1
(43) Pub. Date: Oct. 15, 2026

(54) HIGH ELECTRON MOBILITY TRANSISTOR

(71) Applicant: SUMITOMO ELECTRIC INDUSTRIES, LTD., Osaka (JP)

(72) Inventor: Junji KOTANI, Osaka (JP)

(21) Appl. No.: 19/463,710

(22) Filed: Jan. 29, 2026

(30) Foreign Application Priority Data
Feb. 18, 2025 (JP) 2025-024550

(51) Int. Cl. H10D 62/824; H10D 30/47

(52) U.S. Cl. CPC H10D 62/824; H10D 30/471

(57) ABSTRACT

A high electron mobility transistor is provided and includes a channel layer including a first main surface; and a barrier layer including a second main surface facing the first main surface. The channel layer includes a first nitride semiconductor layer including gallium, and the barrier layer includes a second nitride semiconductor layer including scandium and aluminum. The channel layer has a tensile strain parallel to the first main surface.

### CROSS-REFERENCE TO RELATED APPLICATIONS

This patent application is based on and claims priority to Japanese Patent Application No. 2025-024550 filed on Feb. 18, 2025, the entire contents of which are incorporated herein by reference.

### TECHNICAL FIELD

The present disclosure relates to a high electron mobility transistor.

### BACKGROUND

A high electron mobility transistor (HEMT) including a channel layer formed of gallium nitride (GaN) and a barrier layer formed of aluminum gallium nitride (AlGaN) is known. See, for example, PCT Japanese Translation Patent Publication No. 2021-524164.

### SUMMARY

A high electron mobility transistor of the present disclosure includes: a channel layer including a first main surface; and a barrier layer including a second main surface facing the first main surface. The channel layer includes a first nitride semiconductor layer including gallium. The barrier layer includes a second nitride semiconductor layer including scandium and aluminum. The channel layer has a tensile strain parallel to the first main surface.

### BRIEF DESCRIPTION OF THE DRAWINGS

FIG. 1 is a graph illustrating a relationship between a strain in an a-axis direction in a GaN crystal, and an effective mass of free electrons.

FIG. 2 is a cross-sectional diagram illustrating a high electron mobility transistor according to a first embodiment of the present disclosure.

FIG. 3 is a graph illustrating a relationship between spontaneous polarization and compositions of nitride semiconductors including Al.

FIG. 4 is a graph illustrating a relationship between compositions of nitride semiconductors including Al, and a lattice constant in an a-axis direction.

FIG. 5 is a graph illustrating a relationship between a composition of a second nitride semiconductor layer, and sheet resistance.

FIG. 6 is a graph illustrating a relationship between a composition of an Sc_{0.18(1-}_{y)}Al_{0.82(1-}_{y)}Ga_{y}N layer, and an arithmetic average roughness Ra.

FIG. 7 is a graph illustrating a composition of a barrier layer in a high electron mobility transistor according to a second embodiment of the present disclosure.

FIG. 8 is a graph illustrating a composition of a barrier layer in a high electron mobility transistor according to a third embodiment of the present disclosure.

FIG. 9 is a cross-sectional diagram illustrating a high electron mobility transistor according to a fourth embodiment of the present disclosure.

FIG. 10 is a graph illustrating a composition of a barrier layer in a high electron mobility transistor according to the fourth embodiment.

FIG. 11 is a graph illustrating a composition of a barrier layer in a high electron mobility transistor according to a fifth embodiment of the present disclosure.

### DETAILED DESCRIPTION

In recent years, there has been an increased need for reduction in sheet resistance.

The present disclosure provides a high electron mobility transistor that can be reduced in sheet resistance.

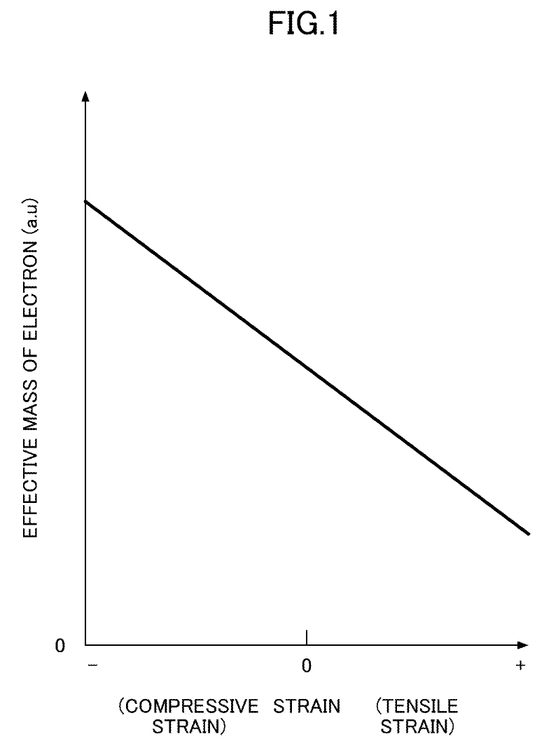

First, the characteristics of a conventional HEMT including a channel layer formed of GaN and a barrier layer formed of AlGaN will be described. FIG. 1 is a graph illustrating a relationship between a strain in an a-axis direction in a GaN crystal, and an effective mass of free electrons. The strain of zero corresponds to the crystal lattice being in a bulk state. Hereinafter, a negative strain is referred to as a compressive strain, and a positive strain is referred to as a tensile strain. The compressive strain is a strain that compresses a crystal lattice thereby decreasing the lattice constant compared to that in the bulk state, and the tensile strain is a strain that pulls a crystal lattice thereby increasing the lattice constant compared to that in the bulk state. In FIG. 1, the tensile strain increases as the positive value of the strain increases, and the compressive strain increases as the negative value of the strain decreases. That is, the magnitude of the strain increases as the absolute value of the positive or negative value of the strain increases.

The lattice constant in the a-axis direction of the GaN crystal is greater than the lattice constant in the a-axis direction of an AlN crystal. Therefore, in the conventional HEMT, in the vicinity of the interface between the channel layer and the barrier layer, the channel layer has a compressive strain in the a-axis direction due to lattice matching with the barrier layer, whereas the barrier layer has a tensile strain in the a-axis direction due to lattice matching with the channel layer.

In the conventional HEMT, it is possible to increase the density of electrons in the channel region by increasing the rate of Al in the barrier layer. In GaN, as illustrated in FIG. 1, the effective mass of electrons increases as the strain in the a-axis direction decreases, i.e., as the compressive strain in the a-axis direction increases. Therefore, in the conventional HEMT, as the rate of Al in the barrier layer increases, the effective mass of electrons in the channel region increases, resulting in a decrease in the mobility of electrons.

Therefore, in the conventional HEMT, even though it is possible to increase the density of electrons in the channel region by increasing the rate of Al in the barrier layer, the mobility of electrons in the channel region decreases. Therefore, it is difficult to increase the conductivity of the channel region, and reduce the sheet resistance.

In view of the above findings, the inventor of the present application has conducted intensive studies to prevent the decrease in the mobility of electrons in the channel region, and has conceived the following embodiments.

### Description of Embodiments of Present Disclosure

First, embodiments of the present disclosure will be described.

1. A high electron mobility transistor according to an aspect of the present disclosure includes: a channel layer including a first main surface; and a barrier layer including a second main surface facing the first main surface. The channel layer includes a first nitride semiconductor layer including gallium. The barrier layer includes a second nitride semiconductor layer including scandium and aluminum. The channel layer has a tensile strain parallel to the first main surface.

Since scandium causes strong spontaneous polarization in the second nitride semiconductor layer, the density of electrons in the channel region increases. Also, since the channel layer has a tensile strain parallel to the first main surface, the mobility of electrons in the channel region increases. This can reduce the sheet resistance.

2. In 1, the number of atoms of the scandium included in the second nitride semiconductor layer may be greater than 0.22 times the number of atoms of the aluminum included in the second nitride semiconductor layer. In this case, the tensile strain parallel to the first main surface is readily generated in the channel layer.

3. In 1 or 2, the second nitride semiconductor layer may further include gallium. In this case, excellent flatness of the top surface of the barrier layer is readily obtained.

4. In 3, the number of atoms of the gallium included in the second nitride semiconductor layer may be 0.3 times or greater than the sum of the number of atoms of the scandium included in the second nitride semiconductor layer, the number of atoms of the aluminum included in the second nitride semiconductor layer, and the number of the atoms of the gallium included in the second nitride semiconductor layer. In this case, especially excellent flatness of the top surface of the barrier layer is readily obtained.

5. In any one of 1 to 4, a ratio of the number of atoms of the scandium included in the second nitride semiconductor layer to the number of atoms of the aluminum included in the second nitride semiconductor layer may be lower at a location farther away from the second main surface. In this case, it is possible to decrease charges in the vicinity of a main surface opposite to the second main surface of the barrier layer, thereby reducing gate leakage.

6. In any one of 1 to 5, the barrier layer may include a third nitride semiconductor layer including aluminum, the second nitride semiconductor layer may be located between the channel layer and the third nitride semiconductor layer, and the third nitride semiconductor layer may have a tensile strain parallel to the first main surface. In this case, it is possible to decrease charges in the vicinity of a main surface opposite to the second main surface of the barrier layer, thereby reducing gate leakage.

7. In 6, the third nitride semiconductor layer may include scandium, and a first ratio of the number of atoms of the scandium included in the second nitride semiconductor layer to the number of atoms of the aluminum included in the second nitride semiconductor layer may be greater than a second ratio of the number of atoms of the scandium included in the third nitride semiconductor layer to the number of atoms of the aluminum included in the third nitride semiconductor layer. When the third nitride semiconductor layer includes scandium, the sheet resistance is readily reduced compared to the case in which the third nitride semiconductor layer does not include scandium. Also, stable crystal growth of the third nitride semiconductor layer is readily performed compared to the case in which the first ratio is equal to the second ratio.

8. In any one of 1 to 7, the second nitride semiconductor layer may further include indium (In). The addition of In can adjust a relationship between the polarization charges and the lattice constant of the second nitride semiconductor layer.

### Details of Embodiments of Present Disclosure

Embodiments of the present disclosure will be described below in detail, but the present disclosure is not limited thereto. In the present specification and drawings, components having substantially the same functional configuration are denoted by the same signs, and thus duplicate description thereof may be omitted. In the present disclosure, “plan view” means viewing an object from a position above the object.

### First Embodiment

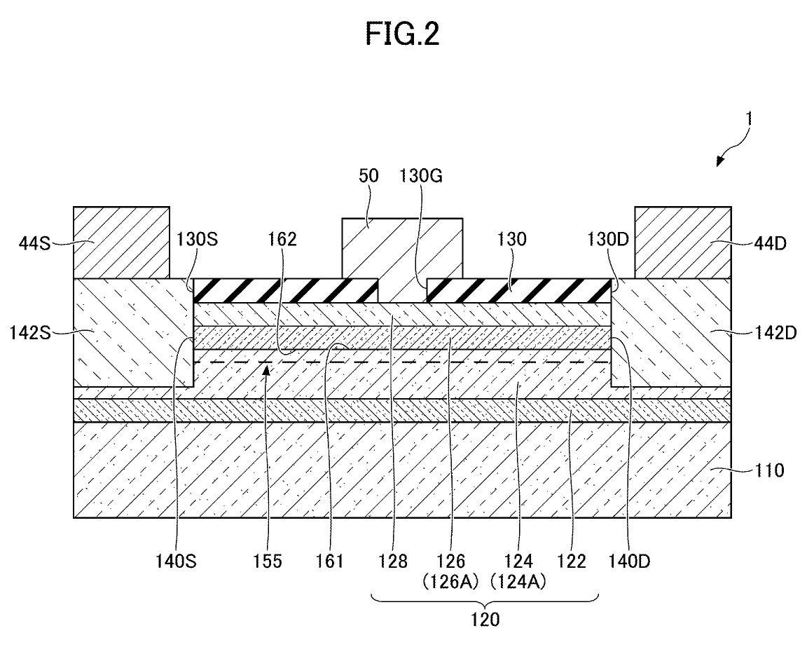

A first embodiment of the present disclosure will be described. The first embodiment relates to a high electron mobility transistor (HEMT). FIG. 2 is a cross-sectional diagram illustrating the high electron mobility transistor according to the first embodiment.

As illustrated in FIG. 2, an HEMT 1 according to the first embodiment includes a substrate 110, a nitride semiconductor laminate structure 120, a regrown layer 142S, a regrown layer 142D, an insulating layer 130, a gate electrode 50, a source electrode 44S, and a drain electrode 44D.

The substrate 110 is, for example, a substrate for growth of a gallium nitride (GaN)-based semiconductor layer, e.g., a semi-insulating silicon carbide (SiC) substrate. When the substrate 110 is an SiC substrate, the top surface of the substrate 110 is a silicon (Si) polar surface. When the surface of the substrate 110 is an Si polar surface, crystal growth of the nitride semiconductor laminate structure 120 is performed from a growth surface of a gallium (Ga) polar surface.

The nitride semiconductor laminate structure 120 includes a buffer layer 122, a channel layer 124, a barrier layer 126, and a cap layer 128.

The buffer layer 122 is located over the substrate 110. The buffer layer 122 is, for example, an aluminum nitride (AlN) layer. The buffer layer 122 may include an AlN layer, and a GaN layer or aluminum gallium nitride (AlGaN) layer located over the AlN layer.

The channel layer 124 is located over the buffer layer 122. The channel layer 124 includes a first nitride semiconductor layer 124A including gallium (Ga). The first nitride semiconductor layer 124A is, for example, an undoped gallium nitride (GaN) layer. The entire channel layer 124 is the first nitride semiconductor layer 124A. The thickness of the channel layer 124 (the first nitride semiconductor layer 124A) is, for example, 20 nanometers (nm) or greater and 800 nm or less. The channel layer 124 includes a top surface as the first main surface 161.

The barrier layer 126 is located over the channel layer 124. The barrier layer 126 includes a bottom surface as a second main surface 162. The second main surface 162 faces the first main surface 161. The barrier layer 126 includes a second nitride semiconductor layer 126A including scandium (Sc) and aluminum (Al). The second nitride semiconductor layer 126A is, for example, an n-type ScAlN or ScAlGaN layer. The entire barrier layer 126 is the second nitride semiconductor layer 126A. The composition of the barrier layer 126 (the second nitride semiconductor layer 126A) is constant from the bottom surface to the top surface. The thickness of the barrier layer 126 (the second nitride semiconductor layer 126A) is, for example, 5 nm or greater and 30 nm or less. The band gap of the barrier layer 126 is greater than the band gap of the channel layer 124.

The channel layer 124 has a tensile strain parallel to the first main surface 161 (hereinafter referred to simply as “tensile strain”), and the barrier layer 126 has a compressive strain parallel to the first main surface 161 (hereinafter referred to simply as “compressive strain”). The tensile strain and the compressive strain are mutually related strains caused by lattice matching between the channel layer 124 and the barrier layer 126. Specifically, when one of the tensile strain or the compressive strain increases, the other increases, and when one of the tensile strain or the compressive strain decreases, the other decreases. In the vicinity of the top surface of the channel layer 124 (the first main surface 161), a channel region 155 including a two-dimensional electron gas (2DEG) exists.

The cap layer 128 is located over the barrier layer 126. The cap layer 128 is, for example, an n-type GaN layer. The thickness of the cap layer 128 is, for example, 3 nm or greater and 10 nm or less.

A recess 140S for a source and a recess 140D for a drain are formed in the cap layer 128, the barrier layer 126, and a portion of the channel layer 124. The recess 140S and the recess 140D penetrate through the cap layer 128 and the barrier layer 126, and extend partially into the channel layer 124. The channel layer 124 is exposed from the recess 140S and the recess 140D.

The insulating layer 130 is located over the cap layer 128. The insulating layer 130 is, for example, a silicon nitride (SiN) film. The thickness of the insulating layer 130 is, for example, 1 nm or greater and 20 nm or less. An opening 130S for a source and an opening 130D for a drain are formed in the insulating layer 130. The opening 130S is continuous with the recess 140S, and the opening 130D is continuous with the recess 140D.

The regrown layer 142S is located over the channel layer 124 in the recess 140S and the opening 130S. The regrown layer 142D is located over the channel layer 124 in the recess 140D and the opening 130D. The regrown layer 142S and the regrown layer 142D are, for example, an n-type GaN layer. The electrical resistance of the regrown layer 142S and the regrown layer 142D is lower than the electrical resistance of the channel region 155.

The source electrode 44S is located on the regrown layer 142S, and the drain electrode 44D is located on the regrown layer 142D. The source electrode 44S is in direct contact with the regrown layer 142S, and the drain electrode 44D is in direct contact with the regrown layer 142D. The source electrode 44S is in ohmic contact with the regrown layer 142S, and the drain electrode 44D is in ohmic contact with the regrown layer 142D.

A opening 130G for a gate is formed in the insulating layer 130. In a plan view, the opening 130G is located between the opening 130S and the opening 130D. The gate electrode 50 is provided over the insulating layer 130, and is in Schottky contact with the nitride semiconductor laminate structure 120 through the opening 130G. A current flowing between the drain electrode 44D and the source electrode 44S through the channel region 155 changes in accordance with a voltage applied to the gate electrode 50.

In the first embodiment, the barrier layer 126 includes the second nitride semiconductor layer 126A including Sc. Sc has the effect of reducing the lattice constant of the crystal of the second nitride semiconductor layer 126A in an a-axis direction to generate strong spontaneous polarization in the second nitride semiconductor layer 126A. Therefore, the density of electrons in the channel region 155 is higher than that in the case in which the second nitride semiconductor layer 126A does not include Sc.

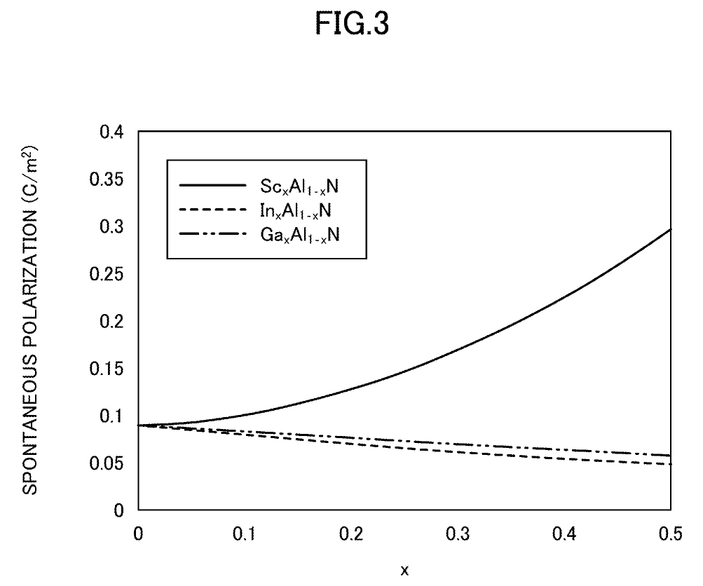

FIG. 3 is a graph illustrating a relationship between spontaneous polarization and compositions of nitride semiconductors including Al. As illustrated in FIG. 3, the spontaneous polarization of aluminum gallium nitride (GaₓAl₁₋ₓN) and indium aluminum nitride (InₓAl₁₋ₓN), where x is a real number of greater than 0 and less than 1, approaches 0 C/m² as the value x increases, whereas the spontaneous polarization of scandium aluminum nitride (ScₓAl₁₋ₓN), where x is a real number of greater than 0 and less than 1, diverges from 0 C/m² as the value x increases. That is, in the ScₓAl₁₋ₓN, the generated spontaneous polarization is stronger as the value x increases. Here, for showing comparison between Sc, In, and Ga, Ga is described at the beginning in the chemical formula of aluminum gallium nitride for the sake of convenience.

In the first embodiment, the channel layer 124 has a tensile strain parallel to the first main surface 161, and the barrier layer 126 has a compressive strain parallel to the first main surface 161. Therefore, as illustrated in FIG. 1, it is possible to reduce the effective mass of electrons in the channel layer 124, thereby increasing the mobility of electrons in the channel region 155. As described above, since the second nitride semiconductor layer 126A includes Sc, the density of electrons in the channel region 155 is high due to an increase in spontaneous polarization. Therefore, according to the first embodiment, it is possible to increase the conductivity by the synergistic effect of the increase in the mobility of electrons and the increase in the density of electrons, thereby reducing the sheet resistance.

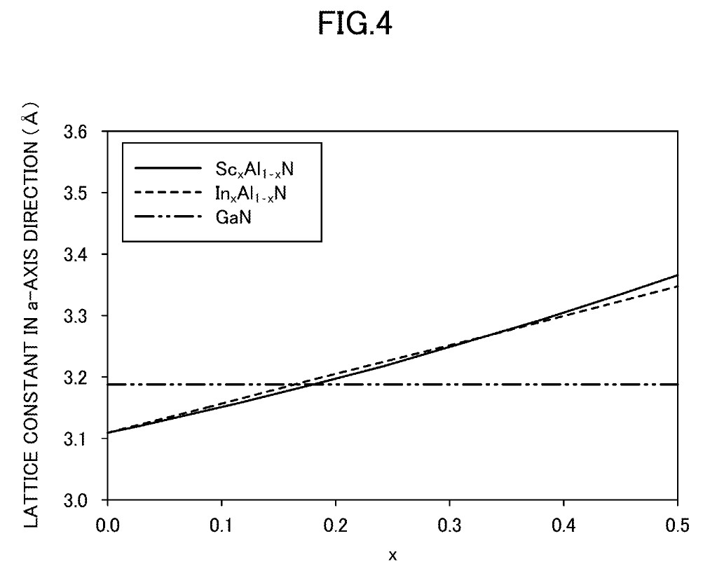

FIG. 4 is a graph illustrating a relationship between compositions of nitride semiconductors including Al, and a lattice constant in an a-axis direction. The lattice constant in the a-axis direction of GaN in bulk is 3.19 angstroms (Å). As illustrated in FIG. 4, for scandium aluminum nitride (ScₓAl₁₋ₓN), the lattice constant in the a-axis direction in bulk is greater than 3.19 Å when the value x is greater than 0.18. When the value x is 0.18, the value of 1−x is 0.82. In this case, the number N (Sc) of atoms of Sc is 0.22 times the number N (Al) of atoms of Al. Therefore, when the first nitride semiconductor layer 124A is a GaN layer and the second nitride semiconductor layer 126A is an ScₓAl₁₋ₓN layer, if the number N (Sc) of atoms of Sc included in the second nitride semiconductor layer 126A is greater than 0.22 times the number N (Al) of atoms of Al included in the second nitride semiconductor layer 126A, the channel layer 124 has a tensile strain parallel to the first main surface 161 and the barrier layer 126 has a compressive strain parallel to the first main surface 161 due to lattice matching with the second nitride semiconductor layer 126A. In the second nitride semiconductor layer 126A, the number N (Sc) of atoms of Sc may be 0.25 times or greater or 0.30 times or greater the number N (Al) of atoms of Al.

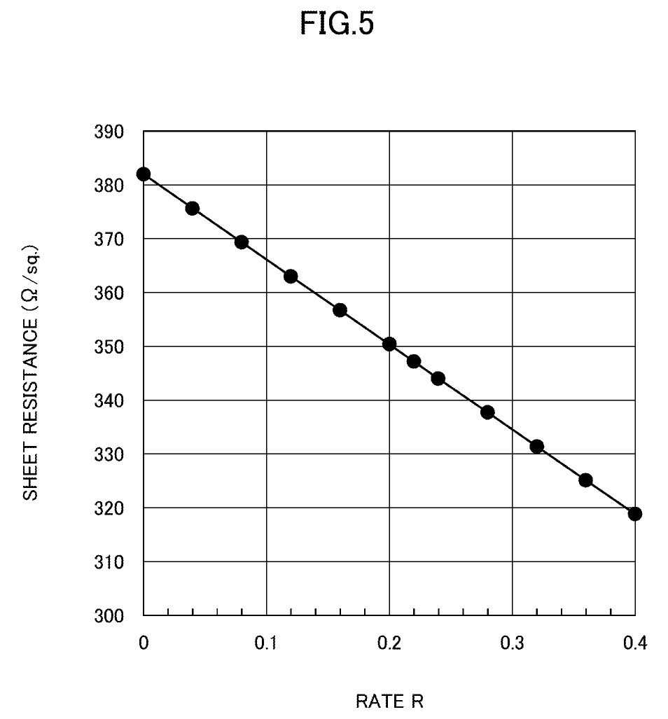

FIG. 5 is a graph illustrating a relationship between a composition of the second nitride semiconductor layer 126A, and the sheet resistance. FIG. 5 shows calculation results of the sheet resistance of the channel region 155 when the first nitride semiconductor layer 124A is a GaN layer and the second nitride semiconductor layer 126A is an ScAlN layer. In this calculation, the spontaneous polarization of ScAlN is assumed to be constant regardless of the composition of ScAlN, the density of electrons in the channel region 155 is assumed to be 1×10¹³ cm⁻³, and the mobility of electrons with no strain being generated in GaN is assumed to be 1,800 cm²/Vs. As illustrated in FIG. 5, the higher a rate R of the number N (Sc) of atoms of Sc to the number N (Al) of atoms of Al, the lower the sheet resistance. This is because, as the rate R is higher, the crystal lattice of the first nitride semiconductor layer 124A being compressed parallel to the first main surface 161 is weakened, thereby reducing the effective mass to increase the mobility of electrons. Note that, when the rate R is 0.22, no strain is generated in GaN. Therefore, when the rate R is greater than 0.22, a tensile strain parallel to the first main surface 161 of the first nitride semiconductor layer 124A is generated.

As illustrated in FIG. 4, for indium aluminum nitride (InₓAl₁₋ₓN), when the value x is greater than 0.17, the lattice constant in the a-axis direction is greater than 3.19 Å. The second nitride semiconductor layer 126A may include indium (In) in addition to Sc and Al. When the second nitride semiconductor layer 126A includes In, even if the value of “the number N (Sc) of atoms of Sc/the number N (Al) of atoms of Al” is smaller than 0.22, the channel layer 124 can include a tensile strain parallel to the first main surface 161, and the barrier layer 126 can have a compressive strain parallel to the first main surface 161. However, as illustrated in FIG. 3, as the amount of In increases, the spontaneous polarization of the second nitride semiconductor layer 126A decreases. When the second nitride semiconductor layer 126A includes In, if the number N (In) of atoms of In is smaller than the number N (Sc) of atoms of Sc, the decrease in the spontaneous polarization is suppressed, and strong spontaneous polarization is readily obtained. If the number N (In) of atoms of In is 0.5 times or less the number N (Sc) of atoms of Sc, even stronger spontaneous polarization is readily obtained.

The second nitride semiconductor layer 126A may include gallium (Ga) in addition to Sc and Al. When the second nitride semiconductor layer 126A includes Ga, excellent flatness of the top surface of the second nitride semiconductor layer 126A is readily obtained. Also, when the first nitride semiconductor layer 124A is a GaN layer and the second nitride semiconductor layer 126A is a scandium aluminum gallium nitride (Sc_{x(1-y)}Al_{(1-x)(1-y)}Ga_{y}N) layer, if the number N (Sc) of atoms of Sc is greater than 0.22 times the number N (Al) of atoms of Al, the channel layer 124 has a tensile strain parallel to the first main surface 161, and the barrier layer 126 has a compressive strain parallel to the first main surface 161. The value y is, for example, 0.9 or less. The second nitride semiconductor layer 126A may include Sc, Al, Ga, and In.

No limitation is imposed on the composition of the second nitride semiconductor layer 126A. However, when the ratio of Sc among the elements excluding N is 0.02 atomic % or more, the sheet resistance is readily reduced. When the ratio of Sc is 0.1 atomic % or more, the sheet resistance is further readily reduced, and when the ratio of Sc is 0.2 atomic % or more, the sheet resistance is even further readily reduced.

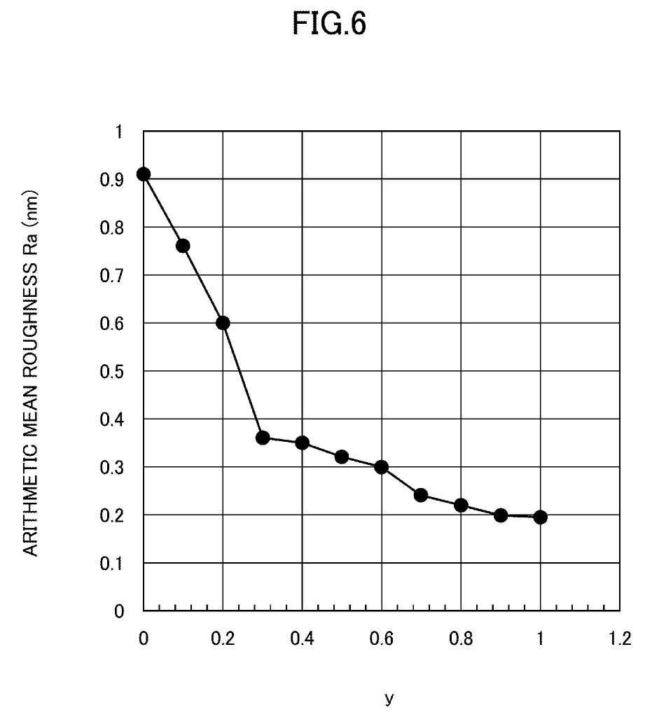

When the second nitride semiconductor layer 126A includes Ga, especially excellent flatness of the top surface of the barrier layer 126 is readily obtained when the number N (Ga) of atoms of Ga included in the second nitride semiconductor layer 126A is 0.3 times or greater than the sum of the number N (Sc) of atoms of Sc, the number N (Al) of atoms of Al, and the number N (Ga) of atoms of Ga. FIG. 6 is a graph illustrating a relationship between a composition of an Sc_{0.18(1}₋_{y)}Al_{0.82(1}₋_{y)}Ga_{y}N layer, and an arithmetic average roughness Ra. As illustrated in FIG. 6, when the value y is 0.3 or greater, especially small arithmetic average roughness Ra is obtained. The number N (Ga) of atoms of Ga in the second nitride semiconductor layer 126A may be 0.5 times or greater or 0.7 times or greater the sum of the number N (Sc) of atoms of Sc, the number N (Al) of atoms of Al, and the number N (Ga) of atoms of Ga. For increasing the crystallinity of the cap layer 128, the arithmetic average roughness Ra of the top surface of the barrier layer 126 is preferably smaller.

### Second Embodiment

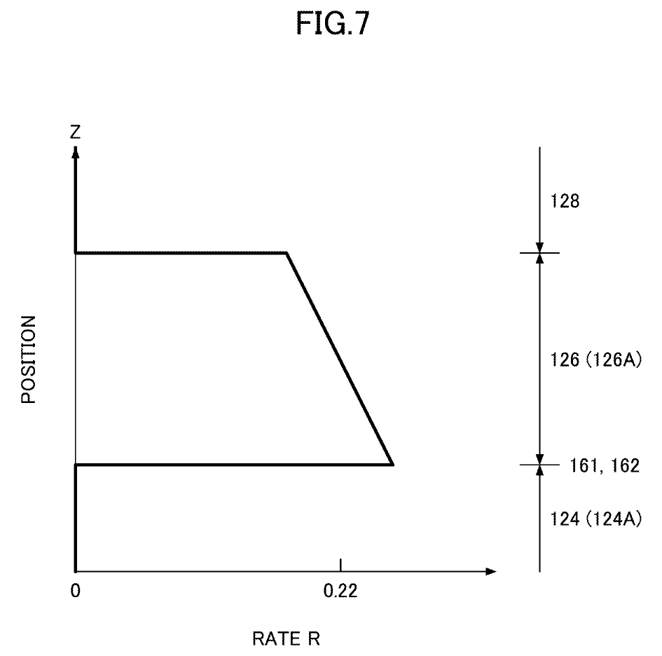

A second embodiment of the present disclosure will be described. The second embodiment is different from the first embodiment in terms of the configuration of the barrier layer. FIG. 7 is a graph illustrating a composition of the barrier layer in a high electron mobility transistor according to the second embodiment.

In the HEMT according to the second embodiment, as illustrated in FIG. 7, the rate R of the number N (Sc) of atoms of Sc to the number N (Al) of atoms of Al in the second nitride semiconductor layer 126A is greater than 0.22 in the second main surface 162 (bottom surface), and decreases with increasing distance from the second main surface 162 toward the cap layer 128. The rate R of the top surface of the second nitride semiconductor layer 126A may be greater or smaller than 0.22, or may be equal to 0.22.

Other configurations of the second embodiment are the same as those of the first embodiment.

According to the second embodiment, as in the first embodiment, it is possible to increase both the mobility of electrons and the density of electrons, thereby reducing the sheet resistance. As described above, when the rate R is greater than 0.22, the channel layer 124 has a tensile strain parallel to the first main surface 161, but the same effect can be obtained even if the lattice constant of a portion away from the second main surface 162 is small. Also, compared to the first embodiment, it is possible to reduce charges in the vicinity of the top surface of the barrier layer 126 (the main surface opposite to the second main surface 162). This can reduce gate leakage. Further, compared to the case in which the rate R is high in the entire second nitride semiconductor layer 126A, stable crystal growth of the second nitride semiconductor layer 126A is readily achieved.

### Third Embodiment

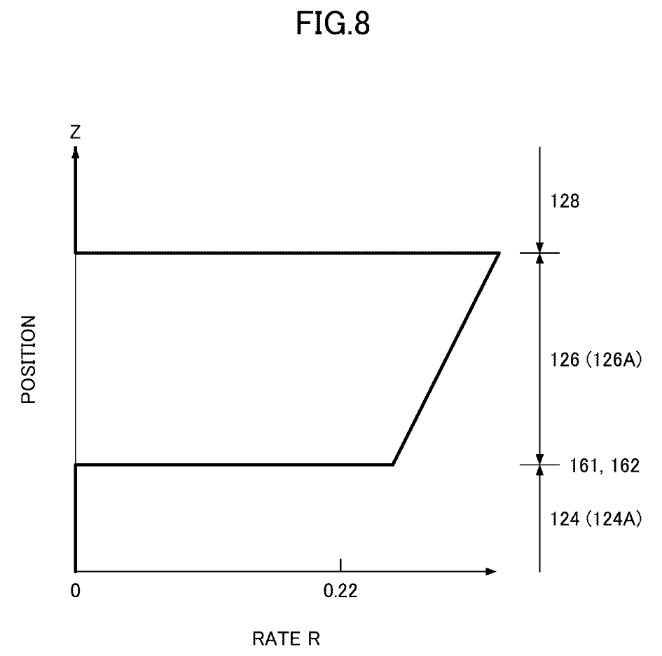

A third embodiment of the present disclosure will be described. The third embodiment is different from the first embodiment in terms of the configuration of the barrier layer. FIG. 8 is a graph illustrating a composition of the barrier layer in a high electron mobility transistor according to the third embodiment.

In the HEMT according to the third embodiment, as illustrated in FIG. 8, the rate R of the number N (Sc) of atoms of Sc to the number N (Al) of atoms of Al in the second nitride semiconductor layer 126A is greater than 0.22 in the second main surface 162 (bottom surface), and increases farther away from the second main surface 162.

Other configurations of the third embodiment are the same as those of the first embodiment.

According to the third embodiment, as in the first embodiment, it is possible to increase both the mobility of electrons and the density of electrons, thereby reducing the sheet resistance. For lattice matching of the second nitride semiconductor layer 126A with the cap layer 128, it may be preferable to increase the rate R in this manner.

### Fourth Embodiment

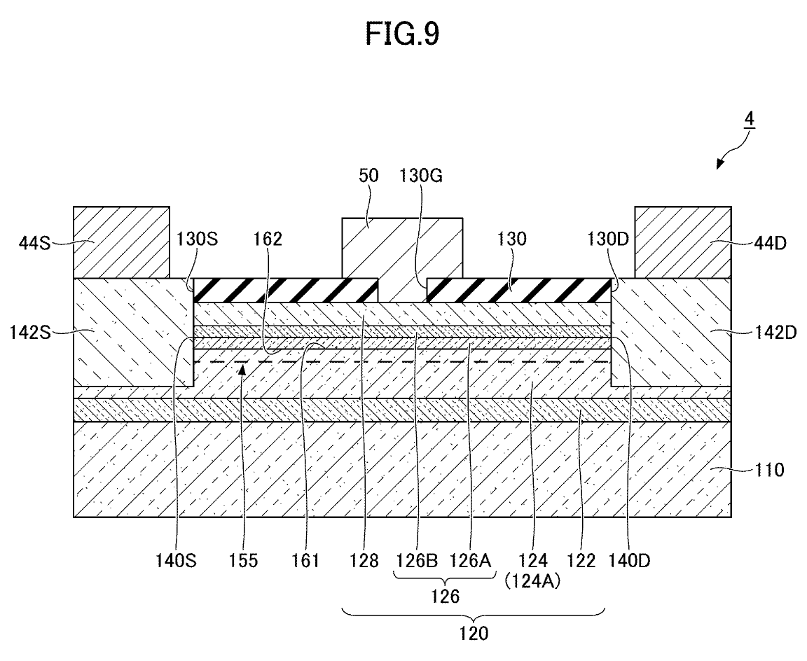

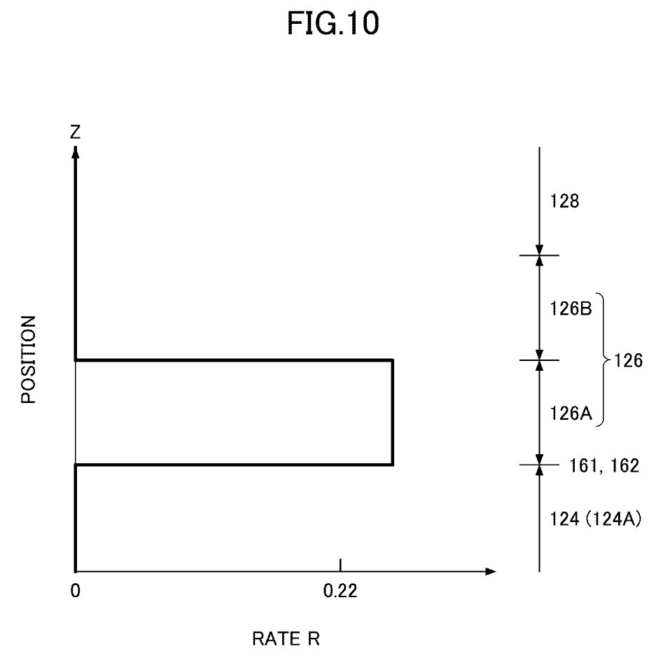

A fourth embodiment of the present disclosure will be described. The fourth embodiment is different from the first embodiment in terms of the configuration of the barrier layer. FIG. 9 is a cross-sectional diagram illustrating a high electron mobility transistor according to the fourth embodiment. FIG. 10 is a graph illustrating a composition of the barrier layer in the high electron mobility transistor according to the fourth embodiment.

In an HEMT 4 according to the fourth embodiment, as illustrated in FIGS. 9 and 10, the barrier layer 126 includes the second nitride semiconductor layer 126A and a third nitride semiconductor layer 126B. The third nitride semiconductor layer 126B includes aluminum (Al) but does not include scandium (Sc). The third nitride semiconductor layer 126B is, for example, an n-type AlN layer or AlGaN layer. The composition of the third nitride semiconductor layer 126B is constant from the bottom surface to the top surface. For example, the thickness of the second nitride semiconductor layer 126A is 2 nm or greater and 10 nm or less, and the thickness of the third nitride semiconductor layer 126B is 2 nm or greater and 10 nm or less. The third nitride semiconductor layer 126B is located over the second nitride semiconductor layer 126A, and the second nitride semiconductor layer 126A is located between the channel layer 124 and the third nitride semiconductor layer 126B. The second nitride semiconductor layer 126A has a compressive strain parallel to the first main surface 161 since the rate R is greater than 0.22. Also, a tensile stress is applied from the second nitride semiconductor layer 126A to the first nitride semiconductor layer 124A. The third nitride semiconductor layer 126B has a tensile strain parallel to the first main surface 161 because the rate R is smaller than 0.22. Also, a compressive stress is applied from the third nitride semiconductor layer 126B to the first nitride semiconductor layer 124A. However, the third nitride semiconductor layer 126B may have a tensile strain, and the influence of the tensile strain of the third nitride semiconductor layer 126B on the compressive strain parallel to the first main surface 161 of the second nitride semiconductor layer 126A is small.

Other configurations of the fourth embodiment are the same as those of the first embodiment.

According to the fourth embodiment, as in the first embodiment, it is possible to increase both the mobility of electrons and the density of electrons, thereby reducing the sheet resistance. Since the barrier layer 126 includes the third nitride semiconductor layer 126B, gate leakage can be reduced, and thus good flatness of the top surface of the barrier layer 126 is readily obtained.

### Fifth Embodiment

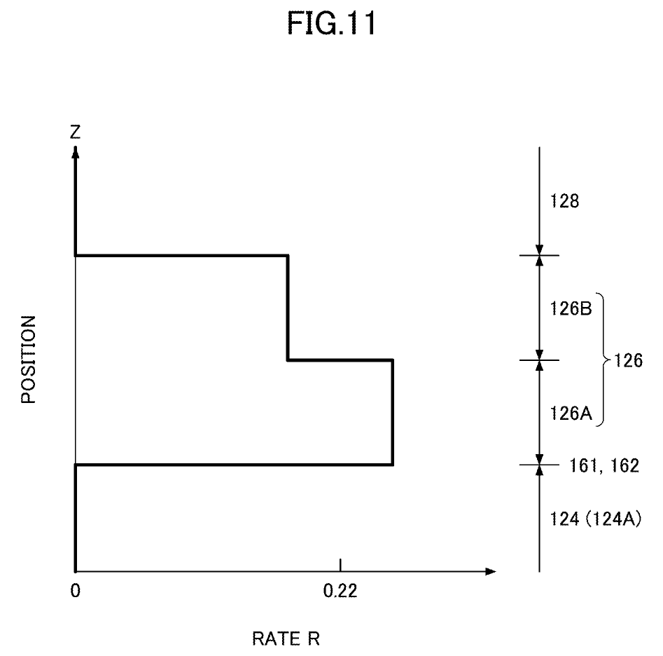

A fifth embodiment of the present disclosure will be described. The fifth embodiment is different from the fourth embodiment in terms of the configuration of the third nitride semiconductor layer. FIG. 11 is a graph illustrating a composition of the barrier layer in a high electron mobility transistor according to the fifth embodiment.

In an HEMT according to the fifth embodiment, as illustrated in FIG. 11, the third nitride semiconductor layer 126B includes scandium (Sc) and aluminum (Al). The third nitride semiconductor layer 126B is, for example, an n-type ScAlN or ScAlGaN layer. The composition of the third nitride semiconductor layer 126B is constant from the bottom surface to the top surface. A first rate R1 of the number N (Sc) of atoms of Sc to the number N (Al) of atoms of Al in the second nitride semiconductor layer 126A is greater than a second rate R2 of the number N (Sc) of atoms of Sc to the number N (Al) of atoms of Al in the third nitride semiconductor layer 126B.

Other configurations of the fifth embodiment are the same as those of the fourth embodiment.

According to the fifth embodiment, as in the first embodiment, it is possible to increase both the mobility of electrons and the density of electrons, thereby reducing the sheet resistance. Since the barrier layer 126 includes the third nitride semiconductor layer 126B, gate leakage can be reduced, and thus good flatness of the top surface of the barrier layer 126 is readily obtained. Also, compared to the case in which the first rate R1 is equal to the second rate R2, stable crystal growth of the third nitride semiconductor layer 126B is readily achieved.

The strain of the channel layer and the strain of the barrier layer can be found, for example, through observation using a high-resolution transmission electron microscope (TEM) with an atomic image level. More specifically, by calculating the average interatomic distance in the observation region, the strain of the channel layer and the strain of the barrier layer can be estimated with high accuracy based on the deviation from the lattice constant of the crystal (bulk).

The composition of the elements included in the barrier layer can be estimated, for example, through X-ray photoelectron spectroscopy (XPS) or energy dispersive X-ray spectroscopy (EDX).

According to the present disclosure, it is possible to reduce sheet resistance.

Although the embodiments have been described above in detail, the present disclosure is not limited to the specific embodiments, and various modifications and alterations are possible within the scope of claims recited.

What is claimed is:

1. A high electron mobility transistor, comprising:
a channel layer including a first main surface; and
a barrier layer including a second main surface facing the first main surface, wherein
the channel layer includes a first nitride semiconductor layer including gallium,
the barrier layer includes a second nitride semiconductor layer including scandium and aluminum, and
the channel layer has a tensile strain parallel to the first main surface.

2. The high electron mobility transistor according to claim 1, wherein
a number of atoms of the scandium included in the second nitride semiconductor layer is greater than 0.22 times a number of atoms of the aluminum included in the second nitride semiconductor layer.

3. The high electron mobility transistor according to claim 1, wherein
the second nitride semiconductor layer further includes gallium.

4. The high electron mobility transistor according to claim 3, wherein
a number of atoms of the gallium included in the second nitride semiconductor layer is 0.3 times or greater than a sum of a number of atoms of the scandium included in the second nitride semiconductor layer, a number of atoms of the aluminum included in the second nitride semiconductor layer, and the number of atoms of the gallium included in the second nitride semiconductor layer.

5. The high electron mobility transistor according to claim 1, wherein
a ratio of a number of atoms of the scandium included in the second nitride semiconductor layer to a number of atoms of the aluminum included in the second nitride semiconductor layer is lower at a location farther away from the second main surface.

6. The high electron mobility transistor according to claim 1, wherein
the barrier layer includes a third nitride semiconductor layer including aluminum,
the second nitride semiconductor layer is located between the channel layer and the third nitride semiconductor layer, and
the third nitride semiconductor layer has a tensile strain parallel to the first main surface.

7. The high electron mobility transistor according to claim 6, wherein
the third nitride semiconductor layer includes scandium, and
a first ratio of a number of atoms of the scandium included in the second nitride semiconductor layer to a number of atoms of the aluminum included in the second nitride semiconductor layer is greater than a second ratio of a number of atoms of the scandium included in the third nitride semiconductor layer to a number of atoms of the aluminum included in the third nitride semiconductor layer.

8. The high electron mobility transistor according to claim 1, wherein
the second nitride semiconductor layer further includes indium.
